(19) United States
(12) Patent Application Publication
(10) Pub. No.: US 2014/0117822 A1
(43) Pub. Date: May 1, 2014

(54) SERVER ENCLOSURE WITH SLIDABLE HARD DISK DRIVE BRACKET

(71) Applicant: HON HAI PRECISION INDUSTRY CO., LTD., New Taipei (TW)

(72) Inventors: CHEN-LU FAN, New Taipei (TW); LI-PING CHEN, New Taipei (TW)

(21) Appl. No.: 13/910,121

(22) Filed: Jun. 5, 2013

(30) Foreign Application Priority Data
Oct. 31, 2012 (TW) 101140434

(51) Int. Cl. H05K 5/02

(52) U.S. Cl. CPC H05K 5/0256
USPC 312/223.2

(57) ABSTRACT

A server enclosure includes a chassis, a slide assembly, and a hard disk drive (HDD) bracket. The chassis includes a base panel and a pair of side panels perpendicularly connected with the base panel. The slide assembly includes an outer slide secured on the base panel, an intermediate slide slidably attached to the outer slide, and an inner slide slidably attached to the intermediate slide. The inner slide is fixed to a bottom of the HDD bracket, thereby driving the HDD bracket sliding into or sliding out from the chassis. The server enclosure further includes a pair of supporting members secured on the base panel. The pair of supporting members is located beside opposite sides of the outer slide and resists against the bottom of the HDD bracket.

### BACKGROUND

1. Technical Field

The present disclosure relates to a server enclosure with a slidable hard disk drive (HDD) bracket.

2. Description of Related Art

A server enclosure includes a chassis and a plurality of HDD brackets mounted in the chassis. A plurality of HDDs is mounted in each of the plurality of HDD brackets. However, the plurality of HDD brackets is fixed in the chassis and immovable relative to the chassis, which does not facilitate users to place HDDs in the HDD bracket or take out the HDDs.

Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded view of an embodiment of a server enclosure, the server enclosure including a slidable HDD bracket.

FIG. 2 is another view of the HDD bracket of FIG. 1.

FIG. 3 is a cross-sectional view of an outer slide, an intermediate slide, and an inner slide of the server enclosure of FIG. 1.

FIG. 4 is an assembled view of a chassis and an outer slide of the server enclosure of FIG. 1.

FIG. 5 is an assembled view of the chassis, the outer slide, and the intermediate slide of the server enclosure of FIG. 1.

FIG. 6 is an assembled view of the server enclosure of FIG. 1.

FIG. 7 is a cross-sectional view of the server enclosure of FIG. 6 taken along line VII-VII.

FIG. 8 is an enlarged view of the circled portion VIII of FIG. 7.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

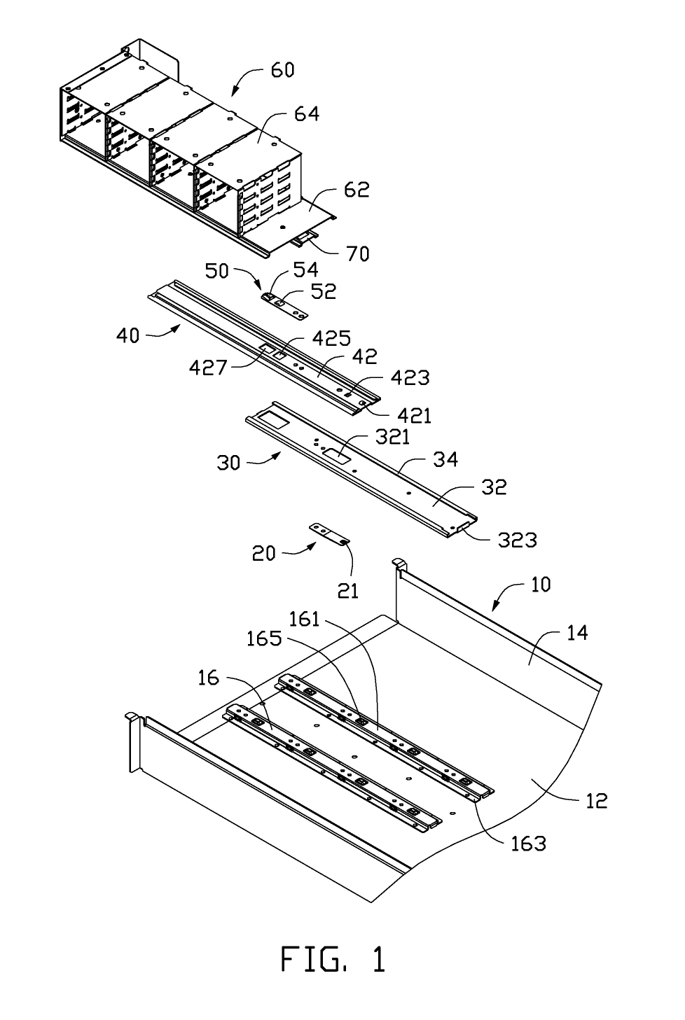

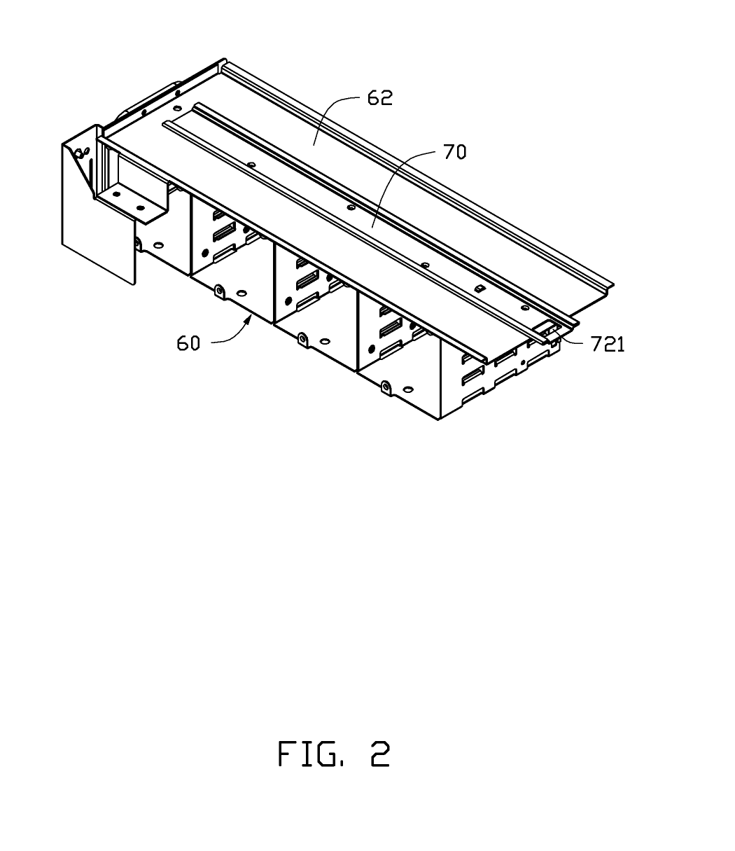

FIGS. 1 to 3 show an embodiment of a server enclosure comprising a chassis 10, a first latch piece 20, an outer slide 70, an intermediate slide 40, a second latch piece 50, a HDD bracket 60, and an inner slide 70 attached to a bottom of the HDD bracket 60.

The chassis 10 includes a base panel 12 and a pair of side panels 14 extending substantially perpendicularly from opposite sides of the base panel 12. A pair of supporting members 16 is mounted on the base panel 12. Each of the pair of supporting members 16 includes a supporting surface 161 and a pair of flanges 163 extending from opposite long edges of the supporting surface 161. The supporting surface 161 has a long, narrow, and rectangular shape. Each of the pair of flanges 163 has an L shape. The supporting surface 161 protrudes upward from the base panel 12 slightly. A plurality of resilient protrusions 165 protrudes upward from the supporting surface 161.

The first latch piece 20 includes a first rectangular main piece and a first protrusion 21 positioned at a distal end of the first rectangular main piece. The second latch piece 50 includes a second rectangular main piece, a second protrusion 54 positioned at a distal end of the second rectangular main piece, and a resilient piece 52 extending from the second rectangular main piece. The resilient piece 52 is adjacent to the second protrusion 54.

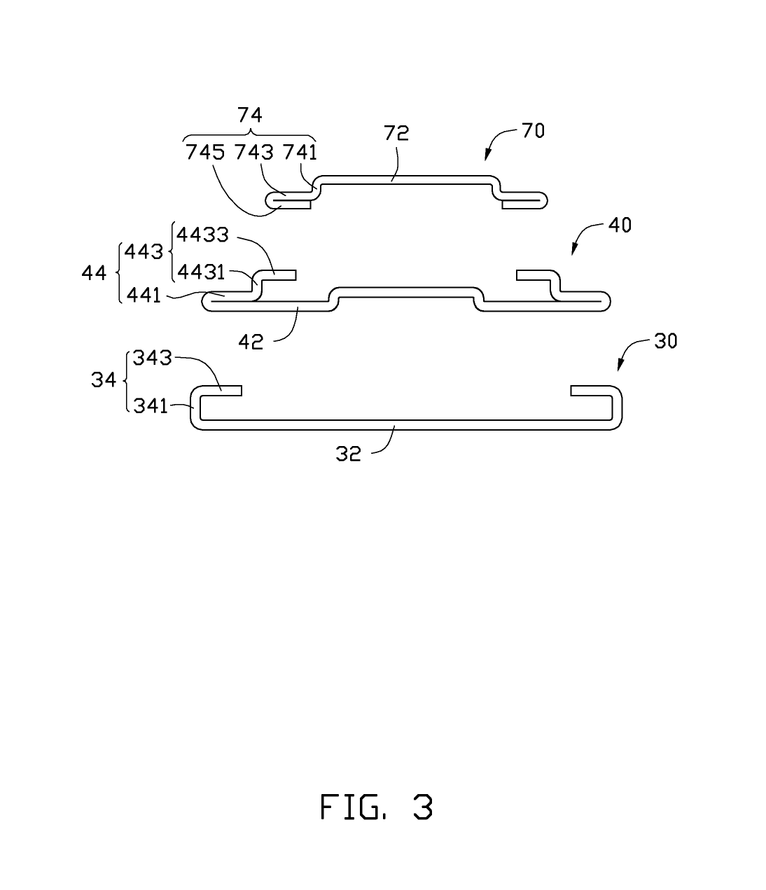

The outer slide 70 includes a first main plate 32 and a pair of first flanges 34 extending from opposite lengthwise edges of the first main plate 32. Each of the pair of first flanges 34 has an L-shape and includes a vertical segment 341 extending substantially perpendicularly from the first main plate 32 and a horizontal segment 343 extending substantially perpendicularly from the vertical segment 341 (see FIG. 3). A blocking flange 323 extends substantially perpendicularly from a distal short edge of the first main plate 32. A first opening 321 is defined in a central portion of the first main plate 32.

The intermediate slide 40 includes a second main plate 42 and a pair of second flanges 44 extending from opposite lengthwise edges of the second main plate 42. The second main plate 42 is not a flat plate. A lengthwise protruding portion 43 protrudes from a central portion of the second main plate 42. Each of the pair of second flanges 44 includes a first segment 441 extending from the second main plate 42 and abutting an inner side of the second main plate 42 and an L-shaped second segment 443 extending from the first segment 441. The L-shaped second segment 443 includes a vertical portion 4431 extending substantially perpendicularly from the first segment 441 and a horizontal portion 4433 extending substantially perpendicularly from the horizontal portion 4431. A first blocking protrusion 421 protrudes upward from the lengthwise protruding portion 43. A second blocking protrusion 423 protrudes downward from the lengthwise protruding portion 43. The first blocking protrusion 421 is located adjacent to a distal end of the intermediate slide 40. The second blocking protrusion 423 is adjacent to the first blocking protrusion 423. A second opening 425 is defined in a central portion of the lengthwise protruding portion 43 corresponding to the resilient piece 52. A third opening 427 is defined in the lengthwise protruding portion 43 corresponding to the second protrusion 54.

The HDD bracket 60 includes a base plate 62 and a plurality of accommodating units 64 attached on the base plate 62. Each of the plurality accommodating units 64 can accommodate a plurality of HDDs.

The inner slide 70 includes a third main plate 72 and a pair of third flanges 74 extending from opposite lengthwise edges of the third main plate 72. Each of the pair of third flanges 74 includes a vertical part 741 extending substantially perpendicularly from the third main plate 72, a horizontal part 743 extending substantially perpendicularly from the vertical part 741, and an overlapping part 745 extending from the horizontal part 743 and abutting the horizontal part 743. A fourth opening 721 is defined in the inner slide 70 and located adjacent to a distal end of the inner slide 70. The third main plate 72 is securely mounted on a bottom surface of the base plate 62. The distal end of the inner slide 70 protrudes from the base plate 62.

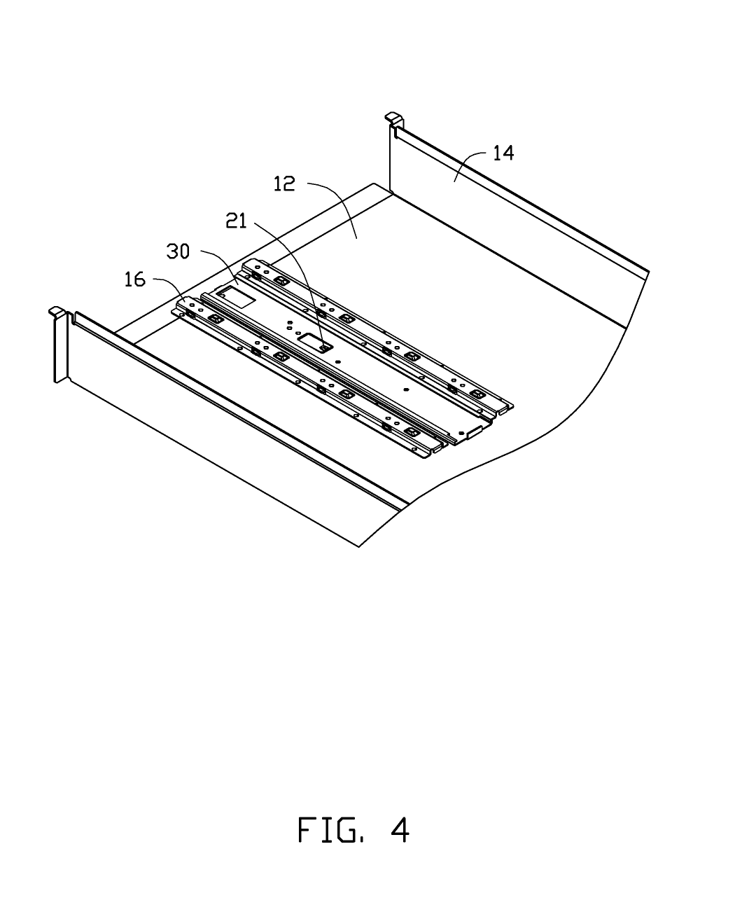

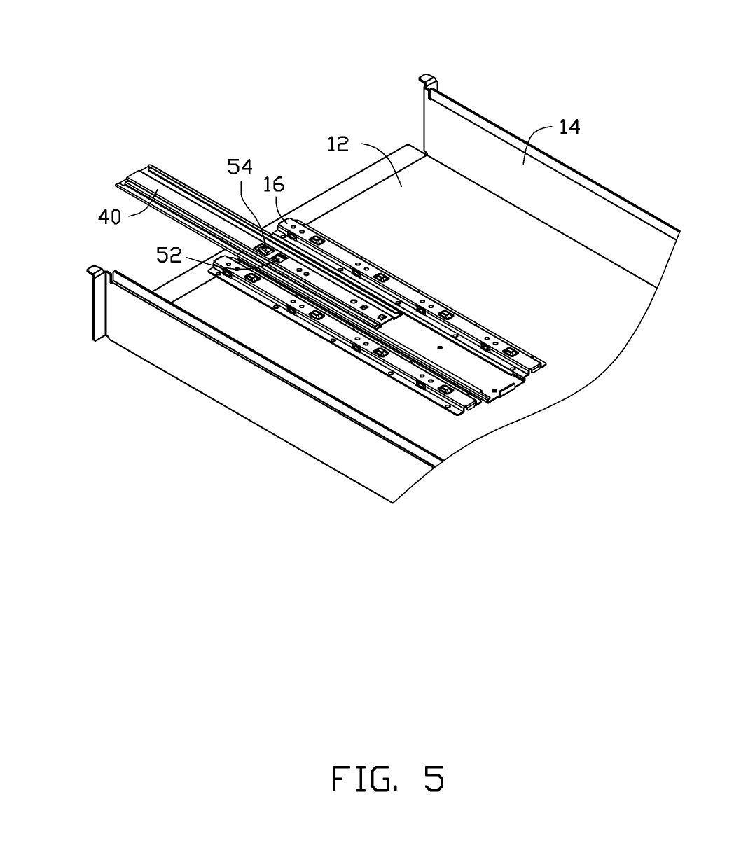

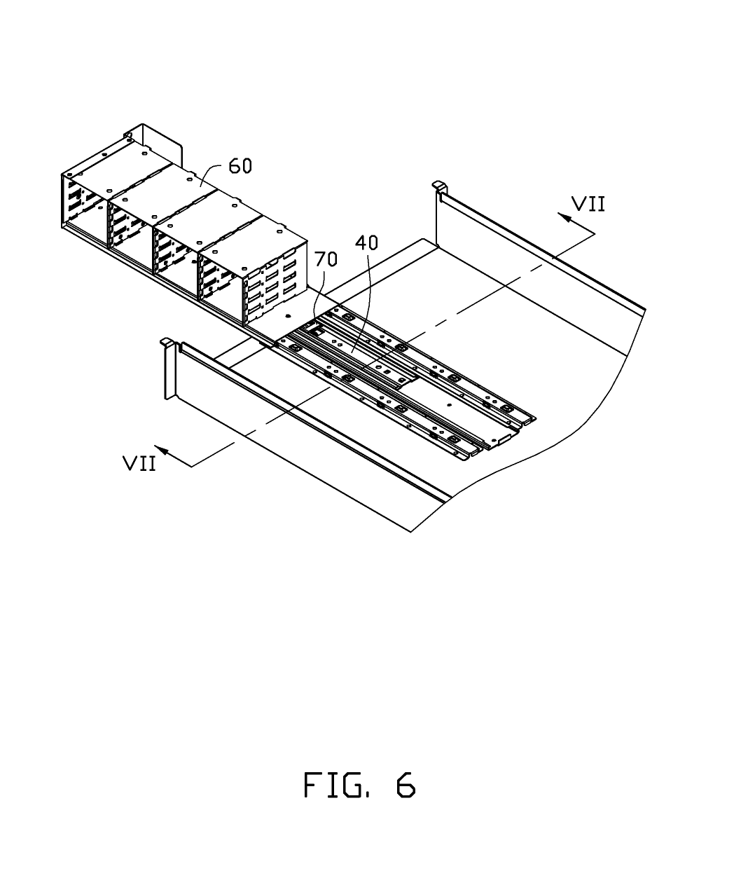

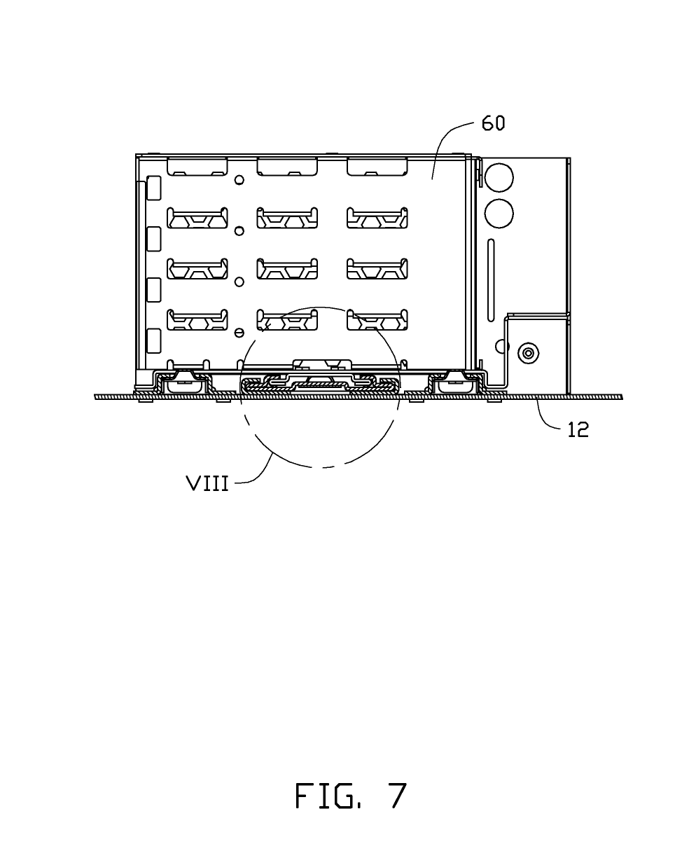

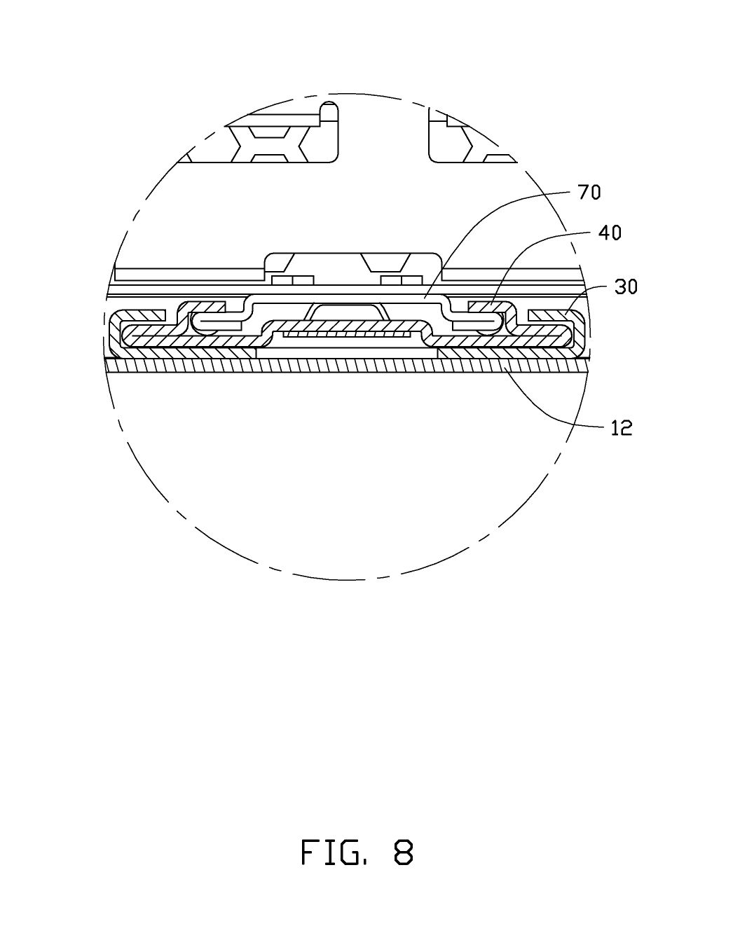

FIGS. 4 to 8 show that in assembly, the first latch piece 20 is attached to a lower surface of the outer slide 30. The first protrusion 21 abuts an edge of the first opening 321 and protrudes upward from the first main plate 32. The outer slide 30 is mounted on the base panel 12 and located between the pair of supporting members 16. The second latch piece 50 is attached to a lower surface of the second main plate 42. The resilient piece 52 protrudes upward from an upper surface of the second main plate 42 via the second opening 425. The second protrusion 54 protrudes upward from the upper surface of the second main plate 42 via the third opening 427. The intermediate slide 40 slides into the outer slide 30. The inner slide 70 slides into the intermediate slide 40. The HDD bracket 60 is slidably mounted in the chassis 10.

When the intermediate slide 40 is slid into the outer slide 30 along a first direction, the first segment 441 is covered and held by the first flange 34 to prevent the intermediate slide 40 from disengaging away from the outer slide 30 along a vertical direction. The L-shaped second segment 443 is exposed and not covered by the first flange 34. When the intermediate slide 40 is slid to a first retracted position, the blocking flange 323 prevents the intermediate slide 40 from continuing to slide along the first direction. When the intermediate slide 40 is slid along a second direction opposite to the first direction and reaches a first extended position, the second blocking portion 423 abuts against the first protrusion 21 to prevent the intermediate slide 40 from continuing to slide along the second direction.

When the inner slide 70 slides into the intermediate slide 40 along the first direction, the horizontal part 743 and the overlapping part 745 is covered and held by the L-shaped second segment 443 to prevent the inner slide 70 from disengaging away from the intermediate slide 40 along the vertical direction. When the inner slide 70 is slid to a second retracted position, the first blocking portion 421 prevents the inner slide 70 from continuing to slide along the first direction. When the inner slide 70 is slid along the second direction opposite to the first direction and reaches a second extended position, the second protrusion 54 is engaged with an edge of the fourth opening 721 to prevent the inner slide 70 from continuing to slide along the second direction.

As the HDD bracket 60 slides into or out from the chassis 10 via the slide assembly, the base plate 62 abuts against the plurality of resilient protrusions 165. The HDD brackets 60 can slide steadily along the slide assembly and the plurality of resilient protrusions 165.

While the present disclosure has been illustrated in detail in one or more embodiments, it is not intended to restrict or in any way limit the scope of the appended claims to such detail. Additional advantages and modifications within the spirit and scope of the present disclosure will readily appear to those skilled in the art, and the present disclosure is not to be limited to the specific details and illustrative examples shown and described.

What is claimed is:

1. A server enclosure comprising:
a chassis comprising a base panel and a pair of supporting members mounted on the base panel;
a slide assembly comprising an outer slide secured to the base panel between the pair of supporting members, an intermediate slide slidably attached to the outer slide, and an inner slide slidably attached to the intermediate slide; and
a hard disk drive (HDD) bracket secured to the inner slide and slidably positioned on the pair of supporting members;
wherein the HDD bracket is capable of sliding together with the inner slide between a first position wherein the HDD bracket is slid into the chassis, and a second position wherein the HDD bracket is slid out from the chassis.

2. The server enclosure of claim 1, wherein the outer slide comprises a first main plate and a pair of first flanges extending from opposite edges of the first main plate; the intermediate slide comprises a second main plate and a pair of second flanges extending from opposite edges of the second main plate; each of the pair of second flanges comprises a first segment extending from the second main plate and abutting an inner side of the second main plate and an L-shaped second segment extending from the first segment,; the first segment is covered and held by the first flange; and the L-shaped second segment is exposed.

3. The server enclosure of claim 2, wherein the inner slide is slidably attached to the intermediate slide and held by the L-shaped second segment.

4. The server enclosure of claim 3, wherein the inner slide comprises a third main plate and a pair of third flanges extending from opposite lengthwise edges of the third main plate, and each of the pair of third flanges is partially located inside the L-shaped second segment and partially exposed out from the L-shaped second segment.

5. The server enclosure of claim 4, wherein each of the pair of third flanges comprises a vertical part extending substantially perpendicularly from the third main plate, a horizontal part extending substantially perpendicularly from the vertical part, and an overlapping part extending from the horizontal part and laying on the horizontal part.

6. The server enclosure of claim 5, wherein the horizontal part and the overlapping part are located inside the L-shaped second segment, and the vertical part is exposed out from the L-shaped second segment.

7. The server enclosure of claim 6, wherein the L-shaped second segment comprises a vertical portion extending substantially perpendicularly from the first segment and a horizontal portion extending substantially perpendicularly from the vertical portion, and the horizontal part abuts an inner surface of the horizontal portion.

8. The server enclosure of claim 1, wherein the HDD bracket comprises a base plate and a plurality of accommodating units mounted on the base plate, and each of the plurality of accommodating units is capable of holding a plurality of HDDs.

9. The server enclosure of claim 8, wherein the inner slide is secured to a bottom of the base plate, and a distal end of the inner slide protrudes from the base plate.

10. The server enclosure of claim 9, wherein an opening is defined in the distal end of the inner side, and a protrusion protrudes from the intermediate slide and is engageable with the opening for limiting a sliding distance of the inner slide.

11. A server enclosure comprising:
a chassis comprising a base panel and a pair of supporting members mounted on the base panel;
a hard disk drive (HDD) bracket; and
a slide assembly mounted between the base panel and the HDD bracket, the slide assembly comprising an outer slide secured on the base panel and located between the pair of supporting members, an intermediate slide slidably attached to the outer slide, and an inner slide slidably attached to the intermediate slide;
wherein the inner slide is secured to a bottom of the HDD bracket, and the HDD bracket is capable of sliding together with the inner slide between a first position, wherein the HDD bracket is slid into the chassis, and a second position, wherein the HDD bracket is slid out from the chassis.

12. The server enclosure of claim 11, wherein the outer slide comprises a first main plate and a pair of first flanges extending from opposite edges of the first main plate; the intermediate slide comprises a second main plate and a pair of second flanges extending from opposite edges of the second main plate; each of the pair of second flanges comprises a first segment extending from the second main plate and abutting an inner side of the second main plate and an L-shaped second segment extending from the first segment, the first segment is covered and held by the first flange; and the L-shaped second segment is exposed.

13. The server enclosure of claim 12, wherein the inner slide is slidably attached to the intermediate slide and held by the L-shaped second segment.

14. The server enclosure of claim 13, wherein the inner slide comprises a third main plate and a pair of third flanges extending from opposite lengthwise edges of the third main plate, and each of the pair of third flanges is partially located inside the L-shaped second segment and partially exposed out from the L-shaped second segment.

15. The server enclosure of claim 14, wherein each of the pair of third flanges comprises a vertical part extending substantially perpendicularly from the third main plate, a horizontal part extending substantially perpendicularly from the vertical part, and an overlapping part extending from the horizontal part and laying on the horizontal part.

16. The server enclosure of claim 15, wherein the horizontal part and the overlapping part are located inside the L-shaped second segment, and the vertical part is exposed out from the L-shaped second segment.

17. The server enclosure of claim 11, wherein the HDD bracket comprises a base plate and a plurality of accommodating units mounted on the base plate, and each of the plurality of accommodating units is capable of holding a plurality of HDDs.

18. The server enclosure of claim 17, wherein the inner slide is secured to a bottom of the base plate, and a distal end of the inner slide protrudes from the base plate.

19. The server enclosure of claim 18, wherein an opening is defined in the distal end of the inner side, and a protrusion protrudes from the intermediate slide and is engageable with the opening for a limiting sliding distance of the inner slide.

20. The server enclosure of claim 18, wherein a plurality of resilient protrusions protrudes from each of the pair of supporting members, and the bottom of the base plate is abut on and slidable along the plurality of resilient protrusions.
